(19) United States
(12) Patent Application Publication
(10) Pub. No.: US 2008/0064128 A1
(43) Pub. Date: Mar. 13, 2008

(54) ANNEALING APPARATUS, ANNEALING METHOD, AND METHOD OF MANUFACTURING A SEMICONDUCTOR DEVICE

(75) Inventor: HIROKAZU ISHIGAKI, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/853,183

(22) Filed: Sep. 11, 2007

(30) Foreign Application Priority Data
Sep. 11, 2006 (JP) 2006-245607

(51) Int. Cl. H01L 21/00; H05B 6/00

(52) U.S. Cl. 438/14; 250/492.2; 257/E21.475

(57) ABSTRACT

The present invention provides an annealing apparatus including a heating unit, a storage unit, a calculating unit, and a control unit. The heating unit anneals a target wafer. The storage unit stores reference data which a shape parameter of a reference element, an annealing temperature, and an electrical characteristic of the reference element are associated with one another. The reference data is obtained by measuring a wafer previously manufactured. The calculating unit determines an actual annealing temperature based on the reference data and measurement data to attain target electrical characteristic. The measurement data include a shape parameter of an element formed in the target wafer. The control unit controls the heating unit to anneal the target wafer at the actual annealing temperature.

### BACKGROUND OF THE INVENTION

1. Field of the Invention

The present invention relates to an annealing apparatus, an annealing method, and a method of manufacturing a semiconductor device.

2. Description of Related Art

In a manufacturing process of a semiconductor device, variations in the gate length, gate oxide film thickness, side wall thickness, or the like of a plurality of transistors included in the semiconductor device lead to variations in the transistor characteristics such as threshold voltage and on-state current. Specifically, there is a problem in that variations in the shape of the transistors lead to variations in the electrical characteristics of the transistors. This problem arises not only among manufacturing lots and wafers but within a wafer, and results in decrease in the manufacturing yield of the semiconductor device.

One way of solving the problem is to control the transistor characteristics by controlling an annealing temperature in a lamp annealing process in the manufacturing process. For example, Japanese Patent Laid-open Application No. 2001-156010 discloses a lamp annealing apparatus and a system of controlling its processing temperature. The lamp annealing apparatus includes a processing chamber of a wafer, a lamp portion for heating the wafer, and a thermometer for measuring the temperature of the wafer. The lamp annealing apparatus further includes a storing portion for storing data of the transistor characteristics in an arbitrary lamp annealing process of an arbitrary product, a calculating portion for calculating data, and a control portion for receiving data from the storing portion and controlling the lamp annealing apparatus. The lamp portion is divided into a plurality of zones, and the output can be adjusted with respect to the respective zones. The thermometer can measure the temperature of portions corresponding to the respective zones of the lamp portion of the wafer.

According to Japanese Patent Laid-open Application No. 2001-156010, the lamp portion is divided into a plurality of concentric zones, and the annealing temperature can be adjusted with respect to the respective plurality of zones. Based on the working history (shape or the like) of the transistor formed up to the previous process, the threshold voltage is predicted, and the annealing temperature is adjusted (controlled) with respect to the respective zones such that the predicted threshold voltage has desired values. This can improve the situation where the electrical characteristics of transistors vary within a wafer.

Japanese Patent Laid-open Application No. Hei 11-3868 discloses related art relating to a lamp annealing apparatus and a lamp annealing method. The lamp annealing apparatus thermally processes a semiconductor wafer. The lamp annealing apparatus has a susceptor or a mount, a plurality of contact temperature sensors, and a plurality of lamps. The susceptor is for the purpose of bringing the semiconductor wafer into a processing chamber, taking the semiconductor wafer out of the processing chamber, and processing the semiconductor wafer with the semiconductor wafer held on the susceptor. The mount holds the semiconductor wafer within the processing chamber. The plurality of contact temperature sensors are embedded in the susceptor or the mount with their temperature detecting portions exposed to the surface of the susceptor or the mount where the semiconductor wafer is mounted. According to signals from the temperature sensors, electric power supplied to the respective lamps can be individually controlled.

However, the inventor of the subject application has recognized that the above related arts have the following problems.

The lamp annealing apparatus disclosed in the above-mentioned Japanese Patent Laid-open Application No. 2001-156010 adjusts the electrical characteristics of the transistors on the surface of the wafer by controlling the temperature of the lamps with respect to the respective concentric zones. However, as the diameter of a substrate (semiconductor wafer) becomes larger in recent years, the electrical characteristics now do not necessarily vary concentrically. For example, there may be a case where a region which is not concentric with the wafer has electrical characteristics different from those of other regions. Such a phenomenon is thought to be caused by, for example, an uneven flow rate of a material gas within a film forming chamber, uneven electric discharge due to change in members provided in the chamber overtime, or the like at the time of formation various kinds of films for the transistors. In particular, with respect to a large diameter semiconductor wafer of recent years, a film has to be formed evenly on a large area, therefore, influence of uneven film forming conditions is outstanding. When the variations are not concentric, it is assumed that the lamp annealing apparatus cannot sufficiently carryout an adjustment resulting in decrease in the manufacturing yield. A technique for controlling the annealing temperature on a substrate more precisely is thus desired.

The lamp annealing apparatus disclosed in Japanese Patent Laid-open Application No. Hei 11-3868 adjusts the electrical characteristics of the transistors on the surface of the wafer by controlling the temperature of the lamps with respect to respective rectangular zones arranged in an X-direction and respective rectangular zones arranged in a Y-direction overlapping the rectangular zones arranged in the X-direction. These lamps basically perform temperature control for rectangular zones. Apparently, temperature control of the intersecting portion is also possible by combining control of the rectangular zones intersecting each other. However, because other portions in the rectangular zones are simultaneously heated, the control thought to be considerably complicated in order to individually attain desired temperature of the respective regions on the substrate. In addition, because the distance between heaters and the substrate is large, sufficient temperature adjustment is thought to be difficult. A technique for controlling the annealing temperature on a substrate more precisely is thus desired.

Further, the lamp annealing apparatus disclosed in the above-mentioned Japanese Patent Laid-open Application No. 2001-156010 uses a predictive equation to predict the threshold voltage, and the annealing temperature is adjusted (controlled) with respect to the respective zones such that the predicted threshold voltage has desired values. Therefore, when the threshold voltage predicted by the predictive equation can not be obtained, the predictive equation has to be reviewed, and it is difficult to promptly respond to the situation. A technique for making a criterion of temperature control more suitable for actual manufacture is thus desired.

### SUMMARY

In order to solve the above-mentioned problems, according to the present invention, there is provided an annealing apparatus including a heating unit, a storage unit, a calculating unit, and a control unit. The heating unit has a plurality of regions and is capable of adjusting an annealing temperature for each of the plurality of regions independently. The storing unit stores reference data in which shape parameters of elements to be formed on the wafer, the annealing temperature, and an electrical characteristic of the elements are associated with one another. The calculating unit determines the annealing temperature based on the reference data and measurement data to attain target electrical characteristic, wherein the measurement data are shape parameters of the elements at positions corresponding to the plurality of regions on the wafer and are measured in manufacturing process. The control unit controls the heating unit such that, for each of the plurality of regions, the elements which are at positions corresponding to the plurality of regions are heated at the determined annealing temperature.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a block diagram illustrating a structure of an annealing apparatus according to a first embodiment of the present invention;

FIG. 2 is a block diagram illustrating an exemplary structure of a heating unit 12 illustrated in FIG. 1;

FIG. 3 is a plan view illustrating a structure of lamp heaters 24 illustrated in FIG. 2;

FIG. 4 is a sectional view illustrating a structure of a part of a semiconductor device manufactured by a method of manufacturing a semiconductor device according to the present invention;

FIG. 5 is a table illustrating exemplary product data stored in a storage unit 32;

FIG. 6 is a table illustrating exemplary measurement data stored in the storage unit 32;

FIG. 7 is a table illustrating exemplary reference data stored in a storage unit 16;

FIG. 8 is a graph illustrating exemplary reference data stored in the storage unit 16;

FIG. 9 is a flow chart illustrating a first embodiment of a method of manufacturing a semiconductor device to which the annealing method according to the present invention is applied;

FIG. 10 is a block diagram illustrating another structure of a heating unit 12 illustrated in FIG. 1;

FIG. 11 is a graph illustrating another exemplary reference data stored in the storage unit 16;

FIG. 12 is a block diagram illustrating a structure of an annealing apparatus according to a second embodiment of the present invention;

FIG. 13 is a table illustrating exemplary accumulated data stored in a storage unit 16;

FIG. 14 is a graph illustrating exemplary accumulated data stored in the storage unit 16;

FIG. 15 is a flow chart illustrating a second embodiment of a method of manufacturing a semiconductor device to which the annealing method according to the present invention is applied; and

FIG. 16 is a graph illustrating another exemplary accumulated data stored in the storage unit 16.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

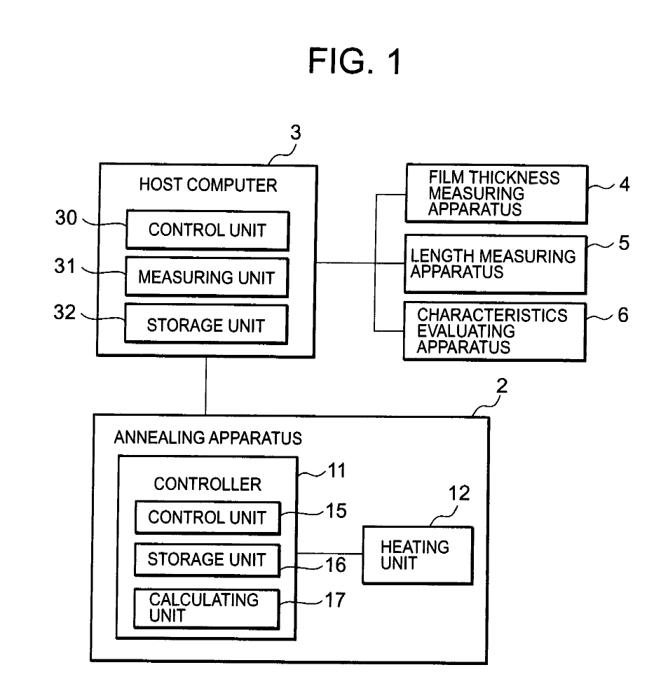

A first embodiment of an annealing apparatus, an annealing method, and a method of manufacturing a semiconductor device according to the present invention are described below with reference to the attached drawings. FIG. 1 is a block diagram illustrating a structure of the first embodiment of an annealing apparatus according to the present invention. An annealing apparatus 2 anneals a semiconductor substrate including semiconductor devices in the process of manufacture at a desired annealing temperature. The annealing is described taking as an example annealing for activating a source/drain. The annealing apparatus 2 is connected to a host computer 3. The annealing apparatus 2 includes a heating unit 12 and a controller 11.

The heating unit 12 has a plurality of regions, and an annealing temperature Tr can be adjusted with respect to the respective plurality of regions. Annealing is performed such that regions of a semiconductor substrate including semiconductor devices in the process of manufacture which correspond to the plurality of regions are at set annealing temperatures Tr under the control of the controller 11. The heating unit 12 is, for example, a plurality of lamp heaters provided in the plurality of regions or a laser which scans with a laser beam regions of the semiconductor substrate which correspond to the plurality of regions, which is described in detail below.

The controller 11 communicates with the host computer 3, and controls the operation of an annealing process of the heating unit 12 according to the command from the host computer 3. The controller 11 includes a control unit 15, a storage unit 16, and a calculating unit 17.

A control unit 15 controls the heating unit 12 and does annealing of the semiconductor substrate at the annealing temperature Tr decided by a calculating unit 17 with respect to the respective plurality of regions on the semiconductor substrate which correspond to the respective plurality of regions of the heating unit 12. The control unit 15 acquires from the host computer 3 various kinds of commands (for example, annealing process start command) and various kinds of data (for example, product data 32-1, measurement data 32-2, threshold voltage Vt, and on-state current Ion, which are described below).

The storage unit 16 stores reference data 16-1.

The reference data 16-1 is data referred to for deciding the annealing temperature Tr in mass production. The reference data 16-1 is obtained in advance in preparation for mass production with respect to the respective kinds of the product by manufacturing a plurality of wafers with various shape parameters (for example, the film thickness Tox of the gate oxide film, the gate length L, and the side wall film thickness Tsw) for evaluation with the annealing temperature Tr being varied, and by measuring the electrical characteristics (for example, the threshold voltage Vt and the on-state current Ion) of the elements on the plurality of wafers. The reference data 16-1 associates the kind of the product, the actually measured shape parameters of the elements in the semiconductor devices, and the annealing temperature Tr0 for attaining target electrical characteristics.

The calculating unit 17 acquires the reference data 16-1 prepared and stored in advance in the storage unit 16. The calculating unit 17 refers to the reference data 16-1 with respect to the respective plurality of regions on the semiconductor substrate, and, based on the measurement data 32-2 (to be described later), and decides the annealing temperature Tr.

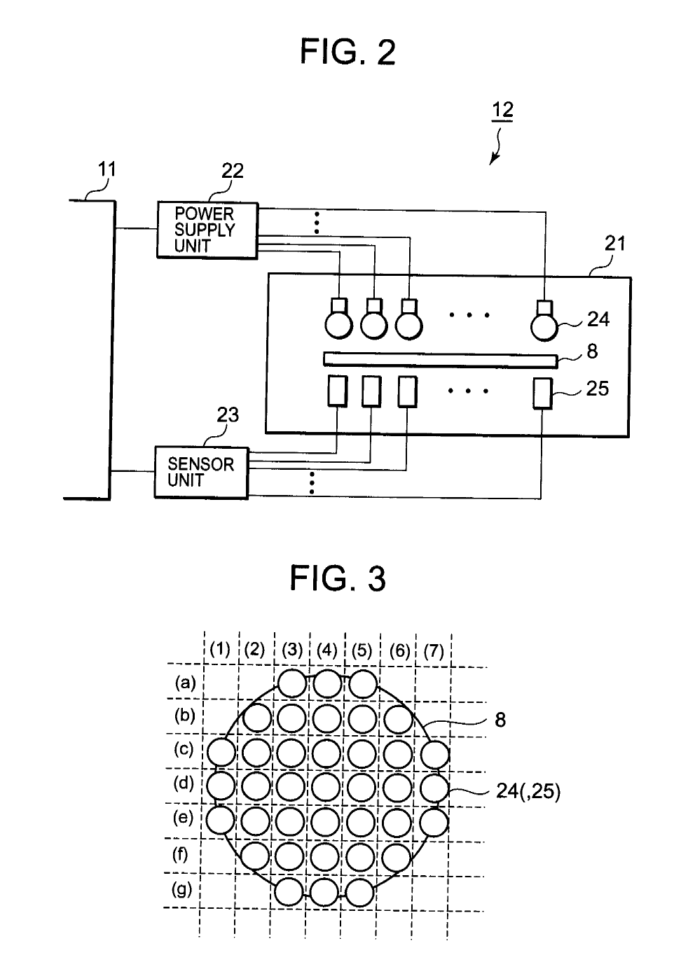

FIG. 2 is a block diagram illustrating an exemplary structure of the heating unit 12 of FIG. 1. Here, the heating unit 12 uses lamp heaters. Specifically, the heating unit 12 includes a chamber 21, a power supply portion 22, a sensor portion 23, a plurality of lamp heaters 24, and a plurality of pyrometers 25.

The chamber 21 is a housing where the annealing is performed. In the chamber 21, a holder (not shown) holds a semiconductor substrate 8 between the plurality of lamp heaters 24 and the plurality of pyrometers 25. An inside atmosphere can be replaced by a desired one by a gas exhaust system (not shown) and a gas supply system (not shown).

The power supply portion 22 supplies current (or voltage) commanded by the control unit 15 to the respective plurality of lamp heaters 24. This makes the respective plurality of lamp heaters 24 generate heat by the current (or voltage) supplied from the power supply portion 22, and the heat is used for annealing the semiconductor substrate 8.

The respective plurality of lamp heaters 24 are infrared lamp heaters arranged in a substantially lattice shape. The plurality of lamp heaters 24 are provided so as to be, when the semiconductor substrate 8 is introduced into the chamber 21, in proximity to the semiconductor substrate 8. Because the plurality of lamp heaters 24 heats an object to be heated mainly with radiant heat, the respective plurality of lamp heaters 24 can mainly heat positions on the opposed semiconductor substrate 8 which correspond to the respective plurality of lamp heaters 24. Specifically, by individually controlling the temperature of the lamp heaters 24, the temperature of regions on the semiconductor substrate 8 which correspond to the lamp heaters 24, respectively, can be individually controlled.

The plurality of pyrometers 25 are provided so as to be opposed to the plurality of lamp heaters 24. Specifically, one pyrometer 25 is provided so as to correspond to one lamp heater 24 at a position opposed to the lamp heater 24. When the lamp heater 24 heats a predetermined region of the semiconductor substrate 8, the pyrometer 25 corresponding to (opposed to) the lamp heater 24 measures the temperature of the predetermined region. The temperatures measured by the plurality of pyrometers 25 are output to the sensor portion 23.

The sensor portion 23 receives the output of the plurality of pyrometers 25, which is output to the control unit 15 in association with the respective plurality of regions.

FIG. 3 is a plan view illustrating a structure of the lamp heaters 24 in FIG. 2. Here, the heating unit 12 for a circular semiconductor substrate 8 is illustrated. The plurality of lamp heaters 24 of the heating unit 12 are arranged in a lattice shape. More particularly, the heating unit 12 is divided into a plurality of lattice-like regions of seven rows ((a)-(g))×seven columns ((1)-(7)). The lamp heaters 24 are arranged in 37 regions which substantially overlie the circular semiconductor substrate 8. The 37 lamp heaters 24 heat the corresponding 37 regions on the semiconductor substrate 8. As a result, substantially the whole surface of the circular semiconductor substrate 8 can be heated. The 37 pyrometers 25 are arranged under the semiconductor substrate 8 in substantially the same way as the 37 lamp heaters 24.

The structure of the heating unit 12 makes it possible to individually control the annealing temperature of the respective plurality of regions of the semiconductor substrate 8. Therefore, even if the shape or the like of the elements (for example, MOS transistors) differ among the plurality of regions, by individually adjusting the annealing temperature with respect to the respective regions, the difference in the shape of the elements can be compensated and the electrical characteristics (for example, the threshold voltage Vt and the on-state current Ion) can be controlled to be substantially the same.

It should be noted that the number 37 is merely exemplary and the present invention is not limited thereto.

With reference to FIG. 1, in manufacturing semiconductor devices, the host computer 3 is connected to manufacturing apparatuses (including the annealing apparatus 2, a film thickness measuring apparatus 4, a length measuring apparatus 5, and a characteristics evaluating apparatus 6, and other apparatus are not shown) and controls the above-mentioned apparatuses. The host computer 3 includes a control portion 30, a measuring unit 31, and a storage unit 32.

The control portion 30 uses various apparatuses (not shown) to control an apparatus for manufacturing a gate oxide film such that a gate oxide film is formed on the semiconductor substrate 8 in a conventionally known manner (for example, by thermal oxidation of the semiconductor substrate 8). Then, the control portion 30 uses various apparatuses (not shown) to control an apparatus for manufacturing MOS transistors such that MOS transistors as elements of the semiconductor devices are formed on the semiconductor substrate 8 in a conventionally known manner. After that, the control portion 30 brings the semiconductor substrate 8 into the annealing apparatus 2 and controls the annealing apparatus 2 so as to carry out annealing. Then, the control portion 30 uses various apparatuses (not shown) to control apparatus for predetermined manufacturing process steps such that predetermined manufacturing process steps (for example, forming an interlayer insulating film and forming wiring) are conducted with respect to the semiconductor substrate 8 after the annealing in a conventionally known manner to form the semiconductor devices.

The measuring unit 31 controls the film thickness measuring apparatus 4 to measure film thickness Tox of the gate oxide film for the MOS transistors with respect to the respective plurality of regions set in advance on the semiconductor substrate 8 (a plurality of positions set in advance on the semiconductor substrate 8, and identified by positional data). The measuring unit 31 refers to the product data 32-1 in the storage unit 32 based on a manufacturing lot number and a wafer number of the semiconductor substrate 8 to acquire the kind of the product. Then, a product lot number of the semiconductor substrate 8, the kind of the product, positional data (x, y) designating the position of the region on the semiconductor substrate 8, and the measured film thickness Tox of the gate oxide film are stored in association with one another with respect to the respective plurality of regions on the semiconductor substrate 8 in the storage unit 32 as the measurement data 32-2.

The measuring unit 31 further controls the length measuring apparatus 5 to measure gate length L and side wall film thickness Tsw of the MOS transistors with respect to the respective plurality of regions on the semiconductor substrate 8 (with respect to the respective positional data). The measuring unit 31 additionally stores the measured gate length L and side wall film thickness Tsw in association with the already stored measurement data 32-2 (the product lot number, the kind of the product, the positional data (x, y), and the film thickness Tox of the gate oxide film) based on the product lot number and the positional data with respect to the respective plurality of regions set on the semiconductor substrate 8 as the measurement data 32-2 in the storage unit 32. Further, the measuring unit 31 controls the characteristics evaluating apparatus 6 to measure the threshold voltages Vt of the MOS transistors with respect to the respective plurality of regions on the semiconductor substrate 8 (with respect to the respective positional data).

The storage unit 32 stores the product data 32-1 and the measurement data 32-2. The product data 32-1 is data set before mass production and associates the manufacturing lot number and the wafer number with the kind of the product. The kind of the product includes data with respect to the shape of the MOS transistor in the product. The measurement data 32-2 is data measured by the measuring unit 31 during mass production, and associates the manufacturing lot number, the kind of the product, the position on the semiconductor substrate 8, and actually measured shape parameters (for example, the film thickness Tox of the gate oxide film, the gate length L, and the side wall film thickness Tsw) of the elements (for example, the MOS transistors) in the semiconductor devices.

The film thickness measuring apparatus 4 measures the film thickness Tox of the insulating film used for the gate oxide film of the MOS transistors under the control of the measuring unit 31. Exemplary film thickness measuring apparatus 4 include an ellipsometer.

The length measuring apparatus 5 measures the gate length L and the side wall film thickness Tsw of the MOS transistors under the control of the measuring unit 31. Exemplary length measuring apparatus 5 include a length measuring scanning electron microscope (SEM).

The characteristics evaluating apparatus 6 measures the threshold voltages Vt of the MOS transistors after the semiconductor devices including the MOS transistors are completed.

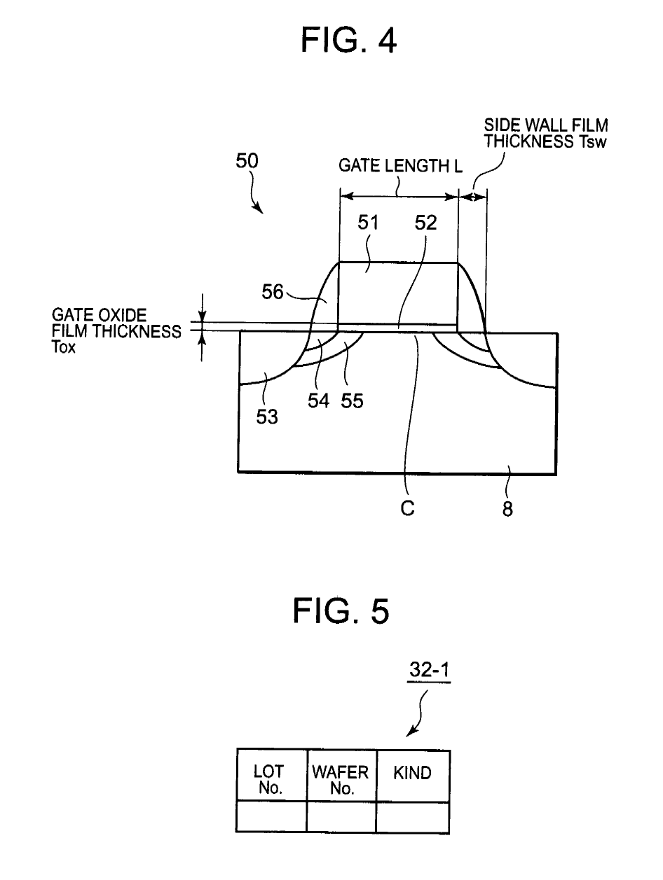

FIG. 4 is a sectional view illustrating a structure of a part of the semiconductor device manufactured by a method of manufacturing a semiconductor device according to the present invention. The semiconductor device includes as an element a MOS transistor 50 as illustrated in the figure. The MOS transistor 50 has a gate electrode 51, a gate oxide film 52, a heavily doped diffusion layer 53 of a first conductivity type (for example, n-type), a diffusion layer 54 of the first conductivity type (for example, n-type), a lightly doped diffusion layer 55 of the first conductivity type (for example, n-type), and side walls 56. The gate oxide film 52 is provided on a channel region C of the semiconductor substrate 8 of a second conductivity type (for example, p-type). The gate electrode 51 is provided so as to cover the gate oxide film 52. The heavily doped diffusion layer 53 of the first conductivity type (for example, n-type), the diffusion layer 54 of the first conductivity type (for example, n-type), and the lightly doped diffusion layer 55 of the first conductivity type (for example, n-type) are provided on both sides of the channel region C to form a source/drain. The side walls 56 are provided on side surfaces of the gate electrode 51 and the gate oxide film 52.

The film thickness Tox of the gate oxide film is film thickness from the surface of the semiconductor substrate 8. The gate length L is width in the direction of the channel region C of the gate electrode 51. The side wall film thickness Tsw is thickness of the side walls 56 in a direction in parallel with the surface of the semiconductor substrate 8. Variations in these film thickness and length vary the threshold voltage Vt (or the on-state current Ion) of the MOS transistors 50. According to the present invention, the threshold voltages Vt (or the on-state current Ion) of the manufactured MOS transistors 50 is controlled by the annealing temperature of the annealing for activating the source/drain (the heavily doped diffusion layer 53 of the first conductivity type, the diffusion layer 54 of the first conductivity type, and the lightly doped diffusion layer 55 of the first conductivity type).

FIG. 5 is a table illustrating exemplary product data stored in the storage unit 32. The product data 32-1 associates “lot No.” as the manufacturing lot number, “wafer No.” as the wafer number for identifying the wafer among a plurality of wafers processed in the respective manufacturing lots, and “kind” as the kind of the product with one another. Here, the manufacturing lot number is set with respect to the respective group of a plurality of the semiconductor substrates 8 for identifying the group of the semiconductor substrates 8. The wafer number is set for the respective wafers for identifying the wafer. The kind of the product indicates the kind of the product manufactured on the semiconductor substrate 8, and target values of the shape parameters of the MOS transistors 50 have been decided with respect to the respective kinds of the product. Therefore, if the kind of the product is identified, designed values of the film thickness Tox of the gate oxide film, the gate length L, the side wall film thickness Tsw, and the threshold voltage Vt are also identified. Specifically, the kind of the product includes these designed values (target values of the shape parameters).

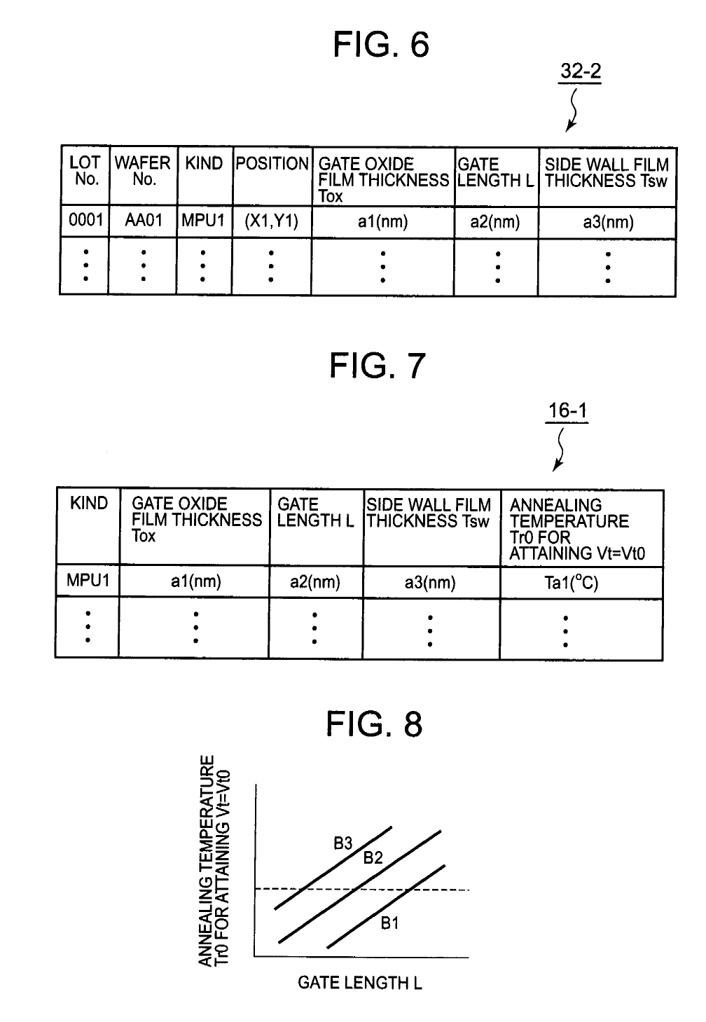

FIG. 6 is a table illustrating exemplary measurement data stored in the storage unit 32. The measurement data 32-2 associates “lot No.” as the manufacturing lot number, “wafer No.” as the wafer number, “kind” as the kind of the product, “position” as the position on the semiconductor substrate 8, “film thickness Tox of gate oxide film”, “gate length L”, and “side wall film thickness Tsw” as the actually measured shape parameters of the MOS transistors 50 with one another.

Here, the manufacturing lot number, the wafer number, and the kind of the product are the same as those in FIG. 5. A position on the semiconductor substrate 8 is a position on the semiconductor substrate 8 which corresponds to the position of a lamp heater 24 among the plurality of lamp heaters 24 of the heating unit 12. For example, the position is defined by coordinates (x, y) when the position on the semiconductor substrate 8 which corresponds to the center position of a lamp heater 24 arranged at (d)-(4) of FIG. 3 is an origin (0, 0), a center line of the row (d) is an x axis, and a center line of the column (4) is a y axis. One position (xi, yj) on the semiconductor substrate 8 is associated with one lamp heater 24. “film thickness Tox of gate oxide film”, “gate length L”, and “side wall film thickness Tsw” of the shape parameters are as described with reference to FIG. 4.

Specifically, with respect to a set of one “lot No.” and one “wafer number”, one “kind”, “positions” for the respective lamp heaters 24, and “film thickness Tox of gate oxide film”, “gate length L”, and “sidewall film thickness Tsw” corresponding to each of the “positions” (for respective lamp heaters 24) are stored.

FIG. 7 is a table illustrating exemplary reference data stored in the storage unit 16. The reference data 16-1 as actual data prepared in advance for mass production associates “kind” as the kind of the product, “film thickness Tox of gate oxide film”, “gate length L”, and “side wall film thickness Tsw” as actually measured shape parameters of the MOS transistors 50, and “annealing temperature Tr0” as an annealing temperature Tr0. Here, because the relationship between the shape of the elements (MOS transistors) and the annealing temperature is necessary, the manufacturing lot number and the position on the semiconductor substrate 8 are omitted.

Here, the kind of the product and the actually measured shape parameters of the MOS transistors 50 are the same as those in FIG. 6. The annealing temperature Tr0 is the annealing temperature Tr0 which is decided with respect to each “kind” described above for attaining a designed value of the threshold voltage (the desired threshold voltage) Vt0. The annealing temperature Tr0 is obtained in advance in preparation for mass production with respect to the respective kinds of the product by manufacturing a plurality of wafers with various shape parameters for evaluation with the annealing temperature Tr varied, and by measuring the electrical characteristics of the elements on the plurality of wafers.

Specifically, with respect to one “kind”, shape parameters of “film thickness Tox of gate oxide film”, “gate length L”, “side wall film thickness Tsw”, and “annealing temperature Tr” for the respective pieces of actually measured data and decided “annealing temperature Tr0” for the respective shape parameters are stored.

FIG. 8 is a graph illustrating exemplary reference data stored in the storage unit 16. A vertical axis denotes the annealing temperature Tr0 for attaining a designed value (target value) of the threshold voltage (desired threshold voltage) Vt0, while a horizontal axis denotes a shape parameter, for example, the gate length L. For example, when the sidewall film thickness Tsw is assumed to be constant, a curve B1 shows a case where the film thickness Tox of the gate oxide film is small, a curve B3 shows a case where the film thickness Tox of the gate oxide film is large, and a curve B2 shows a case where the film thickness Tox of the gate oxide film is medium. Similarly, when the film thickness Tox of the gate oxide film is assumed to be constant, the curve B1 shows a case where the side wall film thickness Tsw is small, the curve B3 shows a case where the side wall film thickness Tsw is large, and the curve B2 shows a case where the side wall film thickness Tsw is medium.

In FIG. 8, when the horizontal axis denotes the side wall film thickness Tsw, the relationship between the gate length L and the film thickness Tox of the gate oxide film is as follows. For example, when the gate length L is assumed to be constant, the curve B1 shows a case where the film thickness Tox of the gate oxide film is small, the curve B3 shows a case where the film thickness Tox of the gate oxide film is large, and the curve B2 shows a case where the film thickness Tox of the gate oxide film is medium. Similarly, when the film thickness Tox of the gate oxide film is assumed to be constant, the curve B1 shows a case where the gate length L is small, the curve B3 shows a case where the gate length L is large, and the curve B2 shows a case where the gate length L is medium.

In FIG. 8, when the horizontal axis denotes the film thickness Tox of the gate oxide film, the relationship between the side wall film thickness Tsw and the gate length L is as follows. For example, when the side wall film thickness Tsw is assumed to be constant invariant, the curve B1 shows a case where the gate length L is small, the curve B3 shows a case where the gate length L is large, and the curve B2 shows a case where the gate length L is medium. Similarly, when the gate length L is assumed to be constant, the curve B1 shows a case where the side wall film thickness Tsw is small, the curve B3 shows a case where the side wall film thickness Tsw is large, and the curve B2 shows a case where the side wall film thickness Tsw is medium.

In the reference data 16-1, the shape parameters (Tox, L, and Tsw) and the annealing temperature Tr0 for attaining the designed value of the threshold voltage Vt0 are data of all the actually measured values (results) measured in actual semiconductor devices, and are not obtained by a predictive equation or a theoretical equation. Therefore, by referring to the reference data 16-1, the annealing temperature can be decided more appropriately.

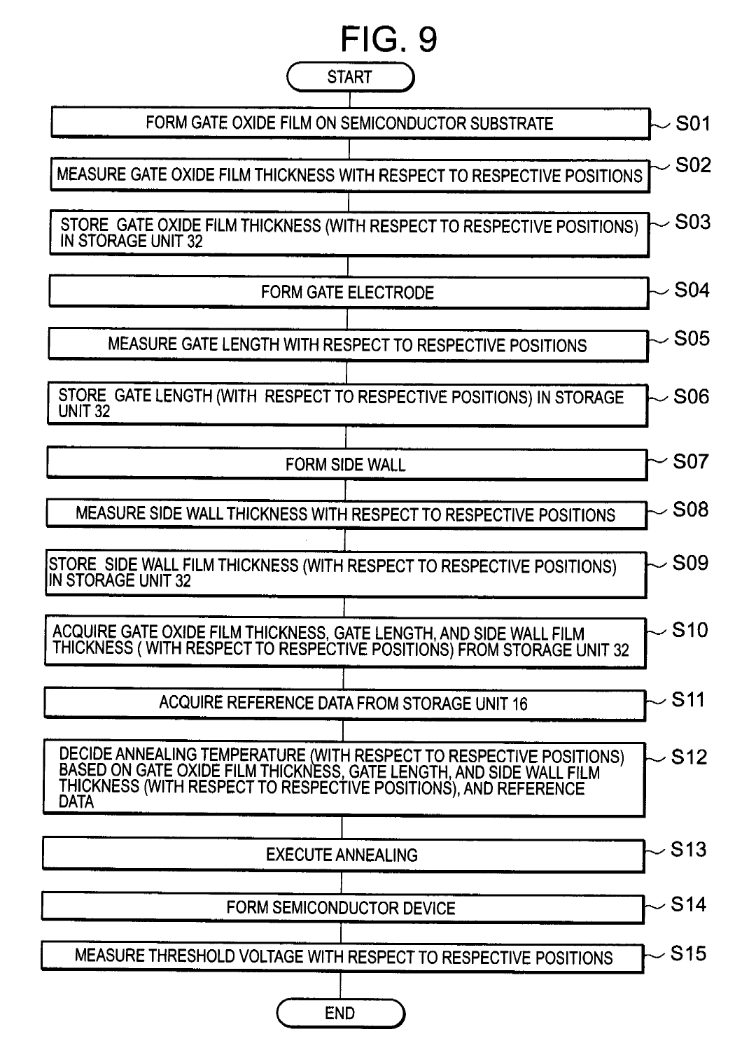

Next, a first embodiment of a method of manufacturing a semiconductor device to which the annealing method according to the present invention is applied is described. FIG. 9 is a flow chart illustrating the first embodiment of the method of manufacturing a semiconductor device to which the annealing method according to the present invention is applied.

### (1) Step S01

The control portion 30 of the host computer 3 uses various apparatuses (not shown) to form the gate oxide film on the semiconductor substrate 8 by a conventionally known method (for example, thermal oxidation of the substrate 8).

### (2) Step S02

The measuring unit 31 controls the film thickness measuring apparatus 4 to measure the film thickness Tox of the gate oxide film with respect to the respective plurality of regions set in advance on the semiconductor substrate 8 (the plurality of positions set in advance on the semiconductor substrate 8).

### (3) Step S03

The measuring unit 31 refers to the product data 32-1 of the storage unit 32 based on the manufacturing lot number and the wafer number of the semiconductor substrate 8 to acquire the kind of the product. Then, the product lot number and the wafer number of the semiconductor substrate 8, the kind of the product, the positional data (x, y) indicating the position of the region on the semiconductor substrate 8, and the measured film thickness Tox of the gate oxide film are associated with one another to be stored in the storage unit 32 as the measurement data 32-2.

### (4) Step S04

The control portion 30 uses various apparatuses (not shown) to form the gate electrode for the MOS transistor 50 serving as an element of a semiconductor device on the semiconductor substrate 8 by a conventionally known method as illustrated in FIG. 4.

### (5) Step S05

The measuring unit 31 controls the length measuring apparatus 5 to measure the gate length L with respect to the respective plurality of regions on the semiconductor substrate 8 (with respect to the respective positional data).

### (6) Step S06

The measuring unit 31 additionally stores the measured gate length L in the storage unit 32 in association with the product lot number and the wafer number, the kind of the product, the positional data (x, y), and the film thickness Tox of the gate oxide film which are already stored in Step S03 based on the product lot number, the wafer number, and the positional data with respect to the respective plurality of regions on the semiconductor substrate 8, as the measurement data 32-2.

### (7) Step S07

The control portion 30 uses various apparatuses (not shown) to form the side walls for the MOS transistor 50 serving as an element of a semiconductor device on the semiconductor substrate 8 in a conventionally known manner as illustrated in FIG. 4.

### (8) Step S08

The measuring unit 31 controls the length measuring apparatus 5 to measure the side wall film thickness Tsw with respect to the respective plurality of regions on the semiconductor substrate 8 (with respect to the respective positional data).

### (9) Step S09

The measuring unit 31 additionally stores the measured side wall film thickness Tsw in the storage unit 32 in association with the product lot number and the wafer number, the kind of the product, the positional data (x, y), the film thickness Tox of the gate oxide film, and the gate length L which are already stored in Steps S03 and S06 based on the product lot number, the wafer number, and the positional data with respect to the respective plurality of regions on the semiconductor substrate 8, as the measurement data 32-2.

### (10) Step S10

The control portion 30 outputs a command to the annealing apparatus 2, brings the semiconductor substrate 8 into the annealing apparatus 2, and causes the annealing apparatus 2 to execute annealing. The control unit 15 of the annealing apparatus 2 acquires the measurement data 32-2 (FIG. 6) from the storage unit 32 of the host computer 3.

### (11) Step S11

The calculating unit 17 acquires the reference data 16-1 (FIGS. 7 and 8) from the storage unit 16.

### (12) Step S12

The calculating unit 17 refers to the reference data 16-1 (FIGS. 7 and 8) based on the measurement data 32-2 (FIG. 6) with respect to the respective plurality of regions on the semiconductor substrate 8 to decide the annealing temperature Tr. Specifically, with respect to the MOS transistor corresponding to the kind of the product, the wafer number, the positional data (x, y), the film thickness Tox of the gate oxide film, the gate length L, and the side wall film thickness Tsw which are included in the measurement data 32-2, the annealing temperature Tr0 for attaining the target value Vt0 of the threshold voltage Vt is extracted from the reference data 16-1.

### (13) Step S13

The control unit 15 executes annealing using the heating unit 12 (for example, as illustrated in FIGS. 2 and 3) at the annealing temperature Tr decided in Step S12 for a predetermined time with respect to the respective plurality of regions on the semiconductor substrate 8.

### (14) Step S14

The control portion 30 of the host computer 3 uses various apparatuses (not shown) and executes predetermined manufacturing process steps (for example, forming an interlayer insulating film and wiring) with respect to the semiconductor substrate 8 after the annealing in a conventionally known manner to form the semiconductor devices.

### (15) Step S15

The measuring unit 31 measures the threshold voltage Vt of the MOS transistor 50 with respect to the respective plurality of regions on the semiconductor substrate 8 (with respect to the respective positional data).

As described above, the semiconductor devices including the elements are manufactured.

According to the present invention, the shape parameters (Tox, L, and Tsw) of the elements (MOS transistors 50) on the semiconductor substrate 8 in the process of manufacture are acquired with respect to the respective plurality of regions, and, based on the shape parameters (Tox, L, and Tsw), reference is made to the reference data 16-1, and the annealing temperature Tr with respect to the respective regions is decided. Because the reference data 16-1 which is the result of an actual past annealing process is used in deciding the annealing temperature, the criterion of temperature control can be made to further conform to actual manufacture (elements). Further, by providing the plurality of regions more densely in a lattice shape than in a case of concentric regions, the annealing temperature Tr on the semiconductor substrate 8 can be controlled more precisely. As a result, substantially the same transistor characteristics can be obtained with respect to all the elements on the semiconductor substrate 8.

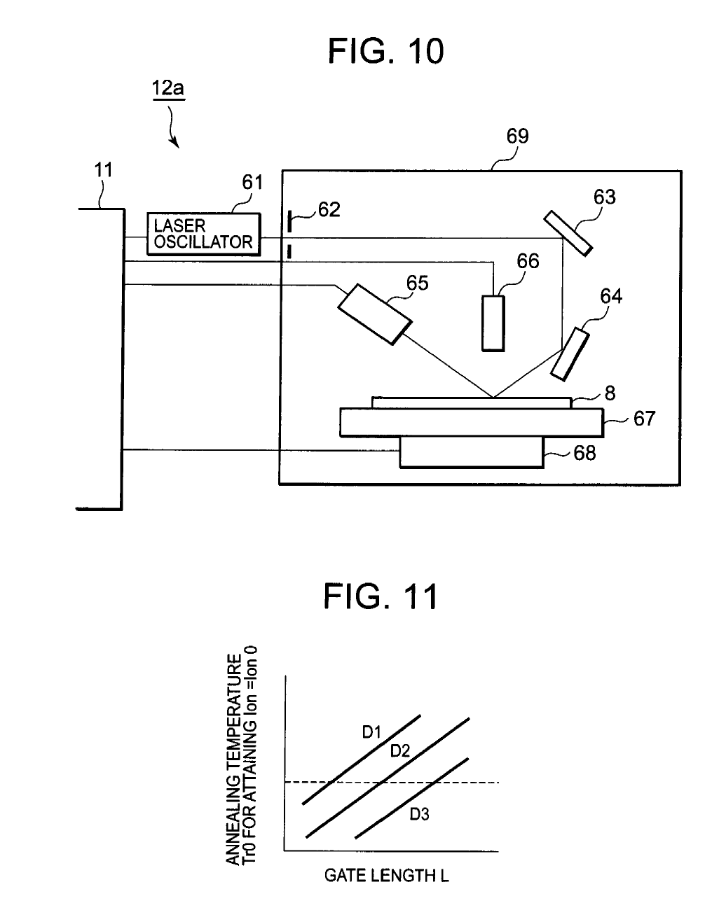

Although the heating unit 12 using lamp heaters is used in the above-mentioned embodiment, a heating unit 12 having another structure can also be used. FIG. 10 is a block diagram illustrating another structure of the heating unit 12 illustrated in FIG. 1. A heating unit 12a includes a laser oscillator 61, a shutter 62, mirrors 63 and 64, a power meter 65, a pyrometer 66, an X-Y stage 67, a driving portion 68, and a chamber 69. The laser oscillator 61 irradiates a controlled amount of a laser beam for heating under the control of the control unit 15. The shutter 62 controls irradiation and no irradiation of a laser beam onto the semiconductor substrate 8. The mirrors 63 and 64 guide the laser beam to a predetermined position. The power meter 65 measures the output of the laser oscillator and outputs the result to the control unit 15. The pyrometer 66 measures the temperature of the position onto which the laser beam is irradiated, and outputs the result to the control unit 15. The X-Y stage 67 holds the semiconductor substrate 8. The driving portion 68 moves the X-Y stage 67 in an X-direction and in a Y-direction under the control of the control unit 15. The chamber 69 is a housing in which the annealing of the substrate 8 is executed. An inside atmosphere can be replaced by a desired one by a gas exhaust system (not shown) and a gas supply system (not shown).

The control unit 15 controls the output of the laser oscillator 61 based on the output of the pyrometer 66 (and the power meter 65) such that the temperature of a target region on the semiconductor substrate 8 becomes the desired annealing temperature Tr. In this case, the control unit 15 controls the operation of the driving portion 68 such that a plurality of regions on the semiconductor substrate 8 are irradiated with the laser beam in order (successively). Specifically, the control unit 15 performs control of the output of the laser oscillator 61 in synchronization with control of the drive of the X-Y stage 67 of the driving portion 68. With the structure, in Step S13, the control unit 15 executes annealing using the heating unit 12 at the annealing temperature Tr, which is decided in Step S12, for a predetermined time with respect to the respective plurality of regions on the semiconductor substrate 8.

As described above, even when the heating unit 12 using a laser is applied, effects similar to those obtained when the lamp heaters are used can be obtained.

In the above-mentioned embodiments, the threshold voltage Vt is used, but other electrical characteristics (transistor characteristics), for example, the on-state current Ion can also be used. When the on-state current Ion is used, in Step S15, the on-state current Ion of the MOS transistor is measured with respect to the respective plurality of regions.

FIG. 11 is a graph illustrating another exemplary reference data stored in the storage unit 16. The reference data 16-1 is obtained in advance in preparation for mass production with respect to the respective kinds of the product by manufacturing a plurality of wafers with various shape parameters for evaluation with the annealing temperature Tr being varied, and by measuring the electrical characteristics of the elements on the plurality of wafers. A vertical axis denotes the annealing temperature Tr0 for attaining the designed value (target value) of the on-state current (desired on-state current) Ion0, while a horizontal axis denotes a shape parameter, for example, the gate length L. For example, when the side wall film thickness Tsw is assumed to be constant, a curve D1 shows a case where the film thickness Tox of the gate oxide film is small, a curve D3 shows a case where the film thickness Tox of the gate oxide film is large, and a curve D2 shows a case where the film thickness Tox of the gate oxide film is medium. Similarly, when the film thickness Tox of the gate oxide film is assumed to be constant, the curve D1 shows a case where the side wall film thickness Tsw is small, the curve D3 shows a case where the side wall thickness Tsw is large, and the curve D2 shows a case where the side wall film thickness Tsw is medium.

In FIG. 11, when the horizontal axis denotes the side wall film thickness Tsw, the relationship between the gate length L and the film thickness Tox of the gate oxide film is as follows. For example, when the gate length L is assumed to be constant, the curve D1 shows a case where the film thickness Tox of the gate oxide film is small, the curve D3 shows a case where the film thickness Tox of the gate oxide film is large, and the curve D2 shows a case where the film thickness Tox of the gate oxide film is medium. Similarly, when the film thickness Tox of the gate oxide film is assumed to be constant, the curve D1 shows a case where the gate length L is small, the curve D3 shows a case where the gate length L is large, and the curve D2 shows a case where the gate length L is medium.

In FIG. 11, when the horizontal axis denotes the film thickness Tox of the gate oxide film, the relationship between the gate length L and the side wall film thickness Tsw is as follows. For example, when the side wall film thickness Tsw is assumed to be constant, the curve D1 shows a case where the gate length L is small, the curve D3 shows a case where the gate length L is large, and the curve D2 shows a case where the gate length L is medium. Similarly, when the gate length L is assumed to be constant, the curve D1 shows a case where the side wall film thickness Tsw is small, the curve D3 shows a case where the side wall film thickness Tsw is large, and the curve D2 shows a case where the side wall film thickness Tsw is medium.

As described above, even when the on-state current Ion is used, effects similar to those obtained when the threshold voltage Vt is used can be obtained.

### Second Embodiment

An annealing apparatus, an annealing method, and a method of manufacturing a semiconductor device according to a second embodiment of the present invention are described below with reference to the attached drawings. The second embodiment is different from the first embodiment in that the reference data is updated based on various kinds of data measured during mass production (for example, measurement data, the decided annealing temperature, and measured threshold voltage).

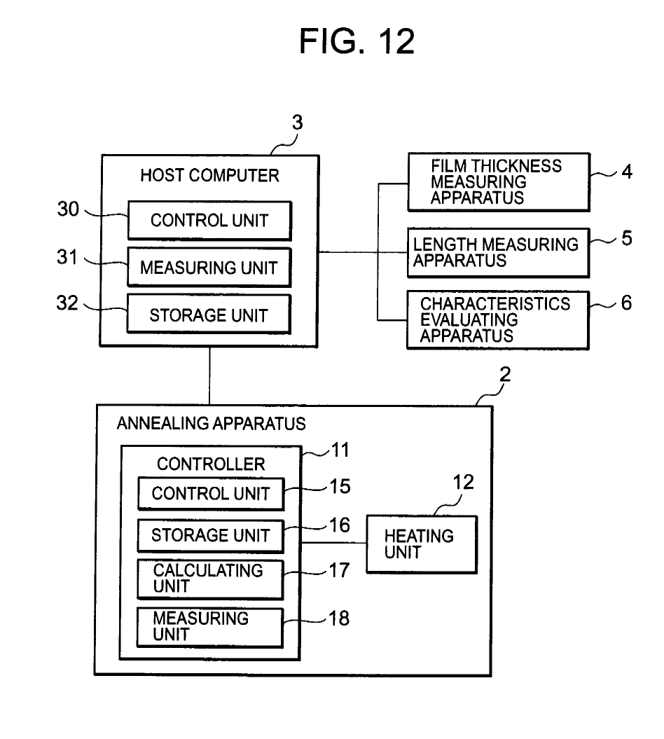

FIG. 12 is a block diagram illustrating a structure of an annealing apparatus according to the second embodiment of the present invention. An annealing apparatus 2 anneals a semiconductor substrate including semiconductor devices in the process of manufacture at a desired annealing temperature. The annealing is exemplified by annealing for activating a source/drain. The annealing apparatus 2 is connected to a host computer 3. The annealing apparatus 2 includes a heating unit 12 and a controller 11. The heating unit 12 has the structure illustrated in FIGS. 2 and 3 and is similar to the heating unit 12 of the first embodiment.

The controller 11 communicates with the host computer 3, and controls the operation of an annealing process of the heating unit 12 in response to the command from the host computer 3. The controller 11 includes a control unit 15, a storage unit 16, a calculating unit 17, and a measuring portion 18. The control unit 15 is similar to the control unit 15 of the first embodiment.

The storage unit 16 stores reference data 16-1 and accumulated data 16-2.

The reference data 16-1 is data referred to for deciding the annealing temperature Tr in mass production. The reference data 16-1 is obtained in advance in preparation for mass production with respect to the respective kinds of the product by manufacturing a plurality of wafers with various shape parameters (for example, the film thickness Tox of the gate oxide film, the gate length L, and the side wall film thickness Tsw) for evaluation with the annealing temperature Tr being varied, and by measuring the electrical characteristics (for example, the threshold voltage Vt and the on-state current Ion) of the elements on the plurality of wafers. The reference data 16-1 associates the kind of the product, the actually measured shape parameters of the elements in the semiconductor devices, and the annealing temperature Tr0 for attaining target electrical characteristics.

On the other hand, the accumulated data 16-2 is various kinds of data (for example, measurement data, the decided annealing temperature, and measured threshold voltage) actually measured by the measuring unit 31 or the like, decided, and acquired during mass production. The accumulated data 16-2 associates the manufacturing lot number and the wafer number, the kind of the product, the position on the semiconductor substrate, the actually measured shape parameters (for example, the film thickness Tox of the gate oxide film, the gate length L, and the side wall film thickness Tsw) of the elements (for example, MOS transistors) in the semiconductor devices, the annealing temperature Tr, and the electrical characteristics (for example, the threshold voltage Vt and the on-state current Ion) of the elements with one another. During mass production, based on the accumulated data 16-2, the reference data 16-1 is updated in real time.

The calculating unit 17 acquires the reference data 16-1 prepared and stored in advance in the storage unit 16. The calculating unit 17 refers to the reference data 16-1 with respect to the respective plurality of regions on the semiconductor substrate, and, based on the measurement data 32-2, and decides the annealing temperature Tr. Further, the calculating unit 17 associates the measurement data 32-2 with the annealing temperature Tr with respect to the respective plurality of regions on the semiconductor substrate, and stores them in the storage unit 16 as the accumulated data 16-2 which is measured, decided, and acquired during mass production. The calculating unit 17 further updates in real time the reference data 16-1 based on the accumulated data 16-2 during mass production.

The measuring portion 18 acquires the threshold voltage Vt (or the on-state current Ion) with respect to the respective plurality of regions on the semiconductor substrate via the control unit 15 from the host computer 3. The measuring portion 18 adds the measured threshold voltage Vt to the accumulated data 16-2 with respect to the respective plurality of regions on the semiconductor substrate, and stores them anew in the storage unit 16 as the accumulated data 16-2 which is measured, decided, and acquired during mass production.

The structures of the host computer 3, the film thickness measuring apparatus 4, the length measuring apparatus 5, and the characteristics evaluating apparatus 6 are similar to those of the first embodiment.

A structure of a part of the semiconductor device manufactured by the method of manufacturing a semiconductor device according to the present invention, exemplary product data stored in the storage unit 32, and exemplary measurement data stored in the storage unit 32 are similar to those of the first embodiment as illustrated in FIGS. 4, 5, and 6, respectively.

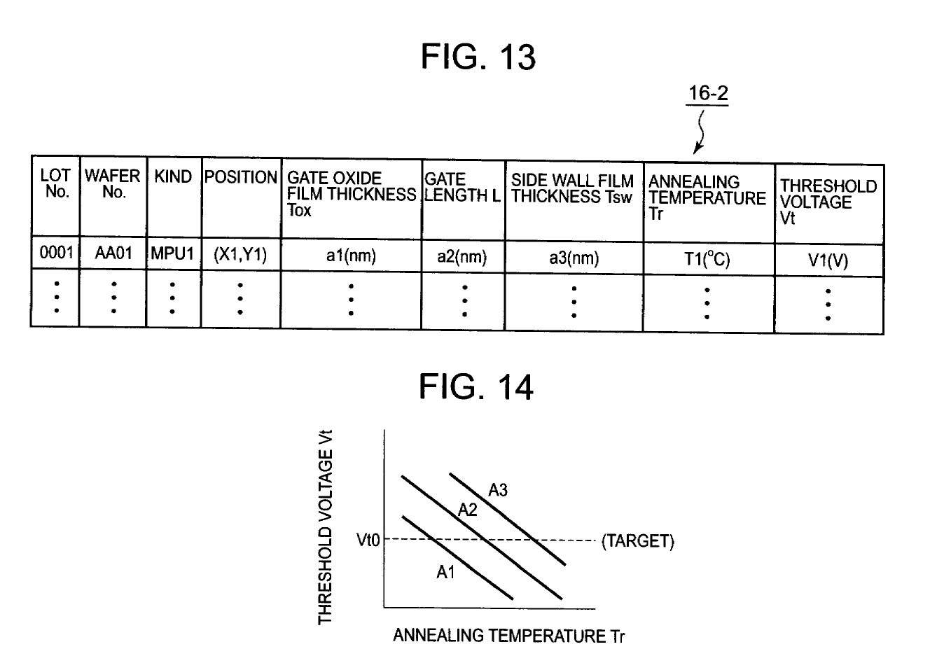

FIG. 13 is a table illustrating exemplary accumulated data stored in the storage unit 16. The accumulated data 16-2 associates “lot No.” as the manufacturing lot number, “wafer No.” as the wafer number, “kind” as the kind of the product, “position” as the position on the semiconductor substrate 8, “film thickness Tox of gate oxide film”, “gate length L”, and “side wall film thickness Tsw” as the actually measured shape parameters of the MOS transistors 50, “annealing temperature Tr” as the annealing temperature Tr, “threshold voltage Vt” as the threshold voltage Vt with one another.

Here, the manufacturing lot number, the wafer number, the kind of the product, the position on the semiconductor substrate 8, and the actually measured shape parameters of the MOS transistors 50 are similar to those illustrated in FIG. 6. The annealing temperature Tr is the annealing temperature decided for each “position” described above based on the measurement data 32-2 with the reference data 16-1 being referred to. The threshold voltage Vt is the threshold voltage measured for each “position” described above when the semiconductor devices are completed after the annealing process.

Specifically, with respect to a set of one “lot No.” and one “wafer number”, one “kind”, “positions” for the respective lamp heaters 24, and “film thickness Tox of gate oxide film”, “gate length L”, “side wall film thickness Tsw”, “annealing temperature Tr”, and “threshold voltage Vt” corresponding to each of the “positions” (for respective lamp heaters 24) are stored.

FIG. 14 is a graph illustrating exemplary accumulated data stored in the storage unit 16. A vertical axis denotes the threshold voltage Vt (the target value of which is Vt0), while a horizontal axis denotes the annealing temperature Tr. For example, when the gate length L and the side wall film thickness Tsw are assumed to be constant, a curve A1 shows a case where the film thickness Tox of the gate oxide film is small, a curve A3 shows a case where the film thickness Tox of the gate oxide film is large, and a curve A2 shows a case where the film thickness Tox of the gate oxide film is medium. Similarly, when the side wall film thickness Tsw and the film thickness Tox of the gate oxide film are assumed to be constant, the curve A1 shows a case where the gate length L is small, the curve A3 shows a case where the gate length L is large, and the curve A2 shows a case where the gate length L is medium. Similarly, when the film thickness Tox of the gate oxide film and the gate length L are assumed to be constant, the curve A1 shows a case where the side wall film thickness Tsw is small, the curve A3 shows a case where the side wall film thickness Tsw is large, and the curve A2 shows a case where the side wall film thickness Tsw is medium.

Exemplary reference data stored in the storage unit 16 are similar to those of the first embodiment as illustrated in FIGS. 7 and 8. However, as described later, data newly generated based on the accumulated data 16-2 are added to the reference data 16-1 and the reference data 16-1 is updated.

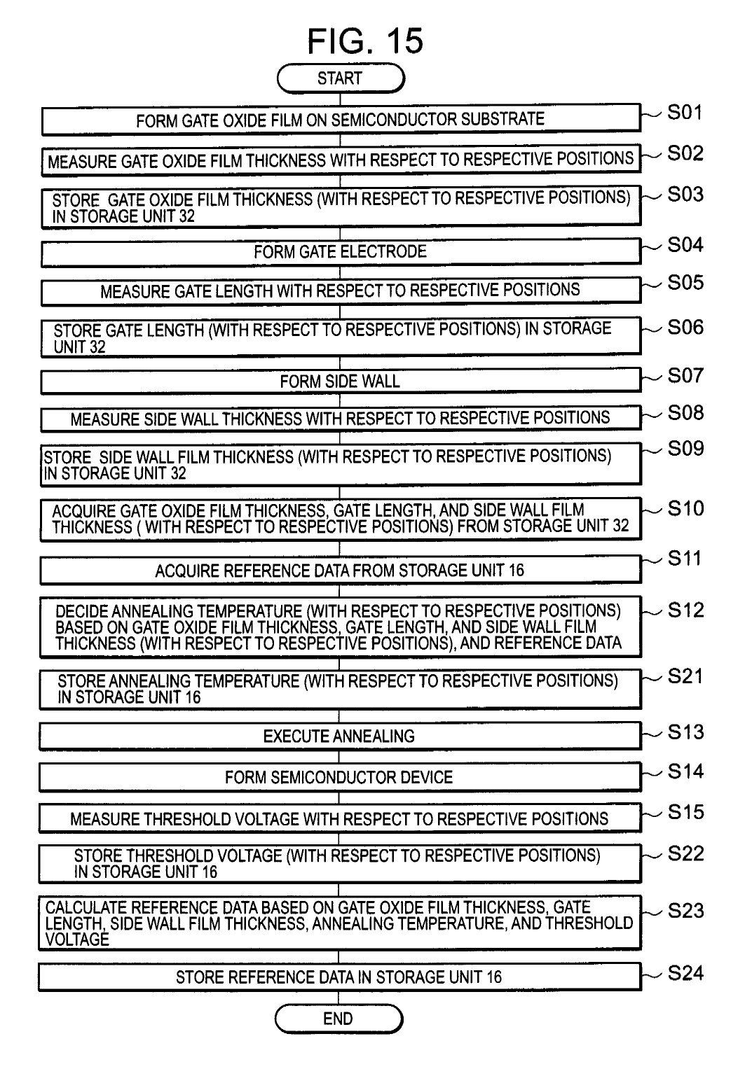

Next, a second embodiment of a method of manufacturing a semiconductor device to which the annealing method according to the present invention is applied is described. FIG. 15 is a flow chart illustrating the second embodiment of the method of manufacturing a semiconductor device to which the annealing method according to the present invention is applied.

### (1) Steps S01 to S12

Steps S01 to S12 are similar to those of the first embodiment.

### (2) Step S21

The calculating unit 17 stores in the storage unit 16 the measurement data 32-2 (the product lot number and the wafer number, the kind of the product, the positional data (x, y), the film thickness Tox of the gate oxide film, the gate length L, and the side wall film thickness Tsw) in association with the decided annealing temperature Tr with respect to the respective plurality of regions on the semiconductor substrate 8, as the accumulated data 16-2 (FIGS. 13 and 14).

### (3) Steps S13 to S15:

Steps S13 to S15 are similar to those of the first embodiment.

### (4) Step S22

The control unit 15 of the annealing apparatus 2 acquires the threshold voltage Vt with respect to the respective plurality of regions on the semiconductor substrate 8 (with respect to the respective positional data) from the host computer 3. Then, the measuring portion 18 additionally stores the measured threshold voltage Vt in the storage unit 16, in association with the product lot number and the wafer number, the kind of the product, the positional data (x, y), the film thickness Tox of the gate oxide film, the gate length L, the sidewall film thickness Tsw, and the annealing temperature Tr which are already stored in Step S21 based on the product lot number, the wafer number, and the positional data with respect to the respective plurality of regions on the semiconductor substrate 8, as the accumulated data 16-2.

### (5) Step S23:

The calculating unit 17 generates data to be added to the reference data 16-1 (FIGS. 7 and 8) (for updating the reference data 16-1) based on the accumulated data 16-2 (FIGS. 13 and 14).

A method of generating the data is described below. First, based on the accumulated data 16-2 illustrated in FIG. 13, a graph as shown in FIG. 14 is generated. Here, the target threshold voltage Vt0 is identified by “kind”. Then, reference is made to the graph to extract the annealing temperature Tr0 for attaining the threshold voltage Vt0 with respect to the MOS transistor having the shape parameters (“film thickness Tox of gate oxide film”, “gate length L”, and “sidewall film thickness Tsw”). Then, the graph illustrated in FIG. 8 is generated which shows the relationship between a shape parameter and the annealing temperature Tr0 for attaining the threshold voltage Vt0. Thus, it is possible to obtain data to be finally added to the reference data 16-1. It should be noted that the calculating unit 17 generates the data by numerical calculations.

### (6) Step S24

The calculating unit 17 stores the generated data to be added to the reference data 16-1 in the storage unit 16 to update the reference data 16-1. The reference data 16-1 updated in the storage unit 16 is acquired (fed back) in Step S1, and is used in Step S12, thereby being effectively used in the manufacture of the semiconductor devices thereafter.

As described above, the semiconductor devices including the elements are manufactured. Also in this case, effects similar to those of the first embodiment can be obtained.

In this embodiment, the reference data 16-1 which is the result of an actual past annealing process is further updated with the result of the most recent actual past annealing process during mass production and is used in deciding the annealing temperature, which makes it possible to further conform the criterion of temperature control to actual manufacture (elements).

Further, similarly to the case of the first embodiment, the heating unit 12 using a laser illustrated in FIG. 10 can be applied, and effects similar to those obtained when the lamp heaters are used can be obtained.

In the above-mentioned embodiments, the threshold voltage Vt is used, but other electrical characteristics (transistor characteristics), for example, the on-state current Ion can also be used. When the on-state current Ion is used, in Step S15, the on-state current Ion of the MOS transistor is measured with respect to the respective plurality of regions. In Step S22, the measured on-state current Ion is stored as the accumulated data 16-2 with respect to the respective plurality of regions. In Step S23, the reference data 16-1 is generated based on the accumulated data 16-2.

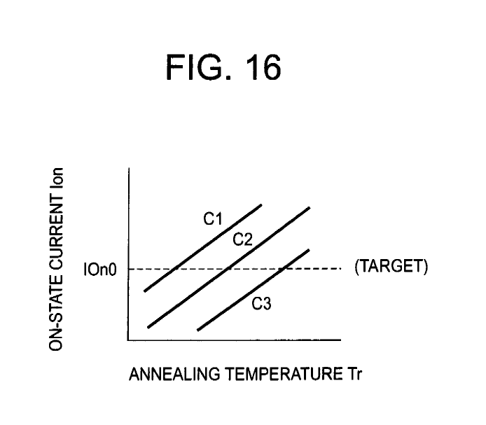

FIG. 16 is a graph illustrating another exemplary accumulated data stored in the storage unit 16. A vertical axis denotes the on-state current Ion (the target value of which is Ion0), while a horizontal axis denotes the annealing temperature Tr. For example, when the gate length L and the side wall film thickness Tsw are assumed to be constant, a curve C1 shows a case where the film thickness Tox of the gate oxide film is small, a curve C3 shows a case where the film thickness Tox of the gate oxide film is large, and a curve C2 shows a case where the film thickness Tox of the gate oxide film is medium.

Similarly, when the side wall film thickness Tsw and the film thickness Tox of the gate oxide film are assumed to be constant, the curve C1 shows a case where the gate length L is small, the curve C3 shows a case where the gate length L is large, and the curve C2 shows a case where the gate length L is medium.

Similarly, when the film thickness Tox of the gate oxide film and the gate length L are assumed to be constant, the curve C1 shows a case where the side wall film thickness Tsw is small, the curve C3 shows a case where the side wall film thickness Tsw is large, and the curve C2 shows a case where the side wall film thickness Tsw is medium.

Similarly to the case of the first embodiment, even when the on-state current Ion is used, effects similar to those obtained when the threshold voltage Vt is used can be obtained.

It is apparent that the present invention is not limited to the above embodiments, but may be modified and changed without departing from the scope and spirit of the invention.

What is claimed is:

1. An annealing apparatus for a semiconductor device, comprising:
a heating unit annealing a target wafer;
a storage unit storing reference data which a shape parameter of a reference element, an annealing temperature, and an electrical characteristic of the reference element are associated with one another, wherein the reference data is obtained by measuring a wafer previously manufactured;
a calculating unit determining an actual annealing temperature based on the reference data and measurement data to attain target electrical characteristic, wherein the measurement data include a shape parameter of an element formed in the target wafer; and
a control unit controlling the heating unit to anneal the target wafer at the actual annealing temperature.

2. An annealing apparatus according to claim 1, wherein the heating unit has a plurality of heating portions arranged in a lattice shape, the control unit is capable of controlling the actual annealing temperature for each of the plurality of heating portions separately.

3. An annealing apparatus according to claim 2, wherein each of the plurality of heating portions comprising an infrared lamp heater.

4. An annealing apparatus according to claim 1, wherein the heating unit comprising a laser heater.

5. An annealing apparatus according to claim 1, wherein the control unit stores an electrical characteristic with respect to the element after being heated, a shape parameter, and the actual annealing temperature in association with one another to update the reference data in the storage unit.

6. An annealing apparatus according to claim 1, wherein:
each of the reference element and the element is a MOS transistor;
each of the electrical characteristic and the target characteristic is a threshold voltage or a on-state current; and
the shape parameter is a gate length or a sidewall thickness, or a gate oxide film thickness.

7. An annealing method for a semiconductor device, comprising:
storing reference data which a shape parameter of a reference element, an annealing temperature, and an electrical characteristic of the reference element are associated with one another, wherein the reference data is obtained by measuring a wafer previously manufactured;
determining an actual annealing temperature based on the reference data and measurement data to attain target electrical characteristic, wherein the measurement data include a shape parameter of an element formed in a target wafer;
controlling a heating unit to anneal the target wafer at the actual annealing temperature.

8. An annealing method according to claim 7, wherein:
the heating unit has a plurality of heating portions arranged in a lattice shape; and
controlling the actual annealing temperature for each of the plurality of heating portions separately.
